(19) United States
(12) Patent Application Publication
(10) Pub. No.: US 2007/0090486 A1
(43) Pub. Date: Apr. 26, 2007

(54) Fuse and method for disconnecting the fuse

(75) Inventors: Satoshi Otsuka, Kawasaki (JP); Toyoji Sawada, Kawasaki (JP); Masato Suga, Kawasaki (JP); Jun Nagayama, Kawasaki (JP); Motonobu Sato, Kawasaki (JP); Takashi Suzuki, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/336,829

(22) Filed: Jan. 23, 2006

(30) Foreign Application Priority Data
Sep. 5, 2005 (JP) 2005-255977

(51) Int. Cl. H01L 29/00

(52) U.S. Cl. 257/529

(57) ABSTRACT

The fuse comprises an interconnection part 14 luding a silicon layer; a contact part 20b connected one end of the interconnection part 14; and a contact part 20aconnected to the other end of the interconnection part 14 and containing a metal material. A current is flowed from the contact part 20bto the contact part 20a to migrate the metal material of the contact part 20a to the silicon layer to thereby change the contact resistance between the interconnection part 14 and the contact part 20a.

### CROSS-REFERENCE TO RELATED APPLICATIONS

This application is based upon and claims the benefit of priority from the prior Japanese Patent Application No. 2005-255977, filed on Sep. 5, 2005, the entire contents of which are incorporated herein by reference.

### BACKGROUND OF THE INVENTION

The present invention relates to a fuse and a method for disconnecting the fuse, more specifically a fuse which can electrically disconnect and reconstruct a circuit, and a method for disconnecting the fuse.

A semiconductor device, such as a memory device, e.g., DRAM, SRAM or others, or a logic device or others, comprises a very large number of devices, and often a partial circuit or memory cell does not normally operate due to various factors of the fabrication process. In such case, if the defective partial circuit or memory cell makes the whole device defective, it will lower the fabrication yield, which will lead to the fabrication cost increase. To prevent this, recently in semiconductor devices, defective circuits or defective memory cells are switched to redundant circuit or redundant memory cells to make them normal to thereby save the defective semiconductor devices.

Some semiconductor devices include a plurality of circuits of different functions formed integral and later have the functions switched, and other semiconductor devices include prescribed circuits fabricated and later have the device characteristics adjusted.

Conventionally, such a semiconductor device is reconstructed by mounting a fuse circuit including a plurality of fuses and disconnecting the fuse after operation tests or others.

As methods for disconnecting a fuse are known the method of flowing high current in the polycrystalline silicon layer forming the fuse to cause self-heating to melt off the fuse, the method of flowing current in a fuse formed of the layer film of polycrystalline silicon layer and silicide layer to thereby aggregate the silicide to increase the resistance of the fuse (see, e.g., Japanese published unexamined patent application No. Hei 11-512879), and other methods.

However, the method of flowing current to melt off the fuse, which requires high current for melting off the polycrystalline silicon and making the transistors for controlling the current and the interconnection for supplying the current large, makes it difficult to downsize the fuse circuit. Explosions occurring in melting off the fuse often crack the inter-layer insulating film on the fuse. The cracks, if grow, are extended to the interconnection layers near the fuse in the worst case, resultantly causing problems of the disconnection of the interconnection layers, etc. To prevent the inter-layer insulating film from cracking, it is effective provide a guard ring, which disadvantageously increases the area of the fuse circuit.

In the method of aggregating the silicide, it is essential to form the fuse having a silicide layer. The silicide layer alone aggregates, and the polycrystalline silicon layer remains below as it is. Accordingly, the resistance increase of the fuse portion is about 10 times at most, and it is difficult to judge the disconnection of the fuse.

### SUMMARY OF THE INVENTION

An object of the present invention is to provide a fuse which can prevent inter-layer insulating film from cracking without making the fuse circuit large and can have a large resistance change between before and after the disconnection of the fuse, and a method for disconnecting the fuse.

According to one aspect of the present invention, there is provided a fuse comprising: an interconnection part including a silicon layer; a first contact part connected to one end of the interconnection part and containing a metal material; and a second contact part connected to the other end of the interconnection part and containing a metal material.

According to another aspect of the present invention, there is provided a fuse comprising: an interconnection part including a silicon layer; a first contact part connected to one end of the interconnection part and containing a metal material; and a second contact part connected to the other end of the interconnection part and containing a metal material, after disconnecting, at least a part of the metal material forming the second contact part being migrated to the interconnection part, and the interconnection part and the second contact part being electrically disconnected.

According to further another aspect of the present invention, there is provided a fuse comprising: an interconnection part including a silicon layer and a metal silicide layer formed on the silicon layer; a first contact part connected to one end of the interconnection part; and a second contact part connected to the other end of the interconnection part, after disconnecting, at least a part of a metal material forming the metal silicide layer being migrated to the interconnection part, and the interconnection part and the second contact part being electrically disconnected.

According to further another aspect of the present invention, there is provided a semiconductor device comprising: a fuse including: an interconnection part including a silicon layer; a first contact part connected to one end of the interconnection part and containing a metal material; and a second contact part connected to the other end of the interconnection part and containing a metal material.

According to further another aspect of the present invention, there is provided a method for disconnecting a fuse comprising an interconnection part including a silicon layer; a first contact part connected to one end of the interconnection part; and a second contact connected to the other end of the interconnection part and containing a metal material, a current being flowed from the first contact part to the second contact part via the interconnection part to migrate the metal material of the second contact part to the silicon layer to thereby change a connection resistance between the interconnection part and the second contact part.

According to further another aspect of the present invention, there is provided a method for disconnecting a fuse comprising an interconnection part including a silicon layer and a metal silicide layer formed on the silicon layer; a first contact part connected to one end of the interconnection part; and a second contact part connected to the other end of the interconnection part, a current being flowed from the first contact part to the second contact part via the interconnection part to migrate a metal material forming the metal silicide layer to a side of the first contact part to thereby change a contact resistance between the interconnection part and the second contact part.

According to the present invention, the fuse comprises an interconnection part including a silicon layer, a first contact part connected to one end of the interconnection part; and a second contact part connected to the other end of the interconnection part and containing a metal material, and a current is flowed from the first contact part to the second contact part to migrate the metal material of the second contact part to the silicon layer to thereby disconnect the fuse, whereby the peripheral elements can be kept from being damaged upon the disconnecting. Thus, the cracking of the inter-layer insulating film can be prevented without making the fuse circuit large. The first contact part and the second contact part can be completely disconnected from each other by migrating the metal material of the second contact part, whereby the resistance change between before and after the disconnecting can be large.

### BRIEF DESCRIPTION OF THE DRAWINGS

FIG. 1 is a plan view of the fuse according to a first embodiment of the present invention.

FIG. 2 is a diagrammatic sectional view of the fuse according to the first embodiment of the present invention.

FIG. 3 is a circuit diagram of one example of the fuse circuit.

FIG. 4 is a diagrammatic sectional view showing the method for disconnecting the fuse according to the first embodiment of the present invention.

FIG. 5A-5C and 6A-6B are sectional views of the fuse according to the first embodiment of the present invention in the steps of the method for fabricating the same.

FIG. 7 is a diagrammatic sectional view of the fuse according to a second embodiment of the present invention.

FIG. 8 is a diagrammatic sectional view showing the method for disconnecting the fuse according to the second embodiment of the present invention.

FIG. 9 is a plan view of the fuse according to a third embodiment of the present invention.

FIG. 10 is a diagrammatic sectional view of the fuse according to the third embodiment of the present invention.

FIG. 11 is a plane view of the fuse according to a fourth embodiment of the present invention.

FIG. 12 is a diagrammatic sectional. view of the fuse according to the fourth embodiment of the present invention.

FIG. 13 is a plan view of the fuse according to a fifth embodiment of the present invention.

FIG. 14 is a plan view of the fuse according to a sixth embodiment of the present invention.

FIG. 15 is a diagrammatic sectional view of the fuse according to the sixth embodiment of the present invention.

FIG. 16 is a diagrammatic sectional view of the fuse according to a seventh embodiment of the present invention.

### DETAILED DESCRIPTION OF THE PREFERRED EMBODIMENTS

[A First Embodiment]

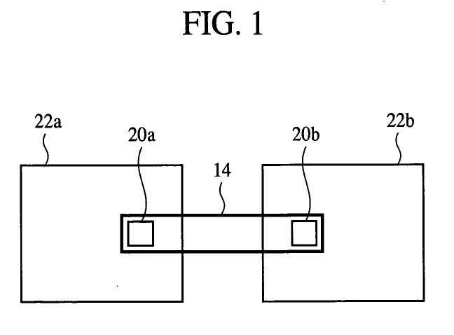

The fuse and the method for disconnecting the fuse according to a fist embodiment of the present invention will be explained with reference to FIGS. 1 to 6B.

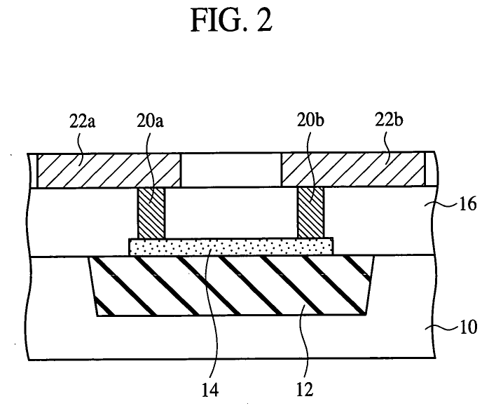

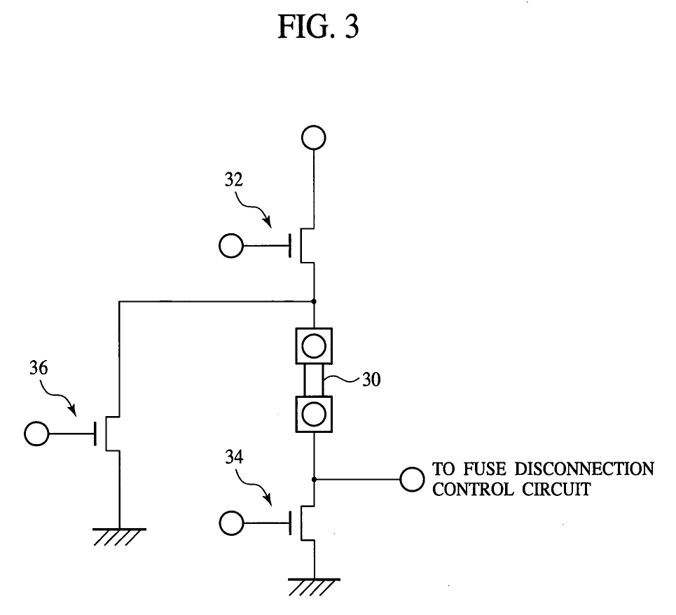

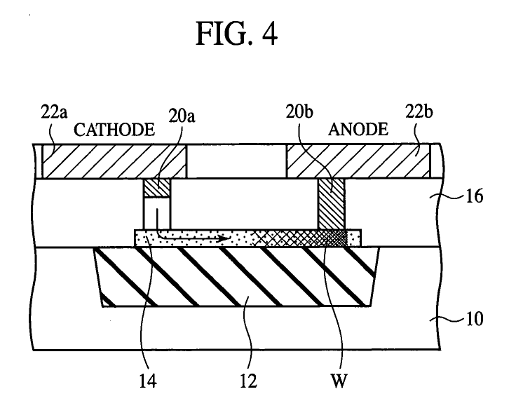

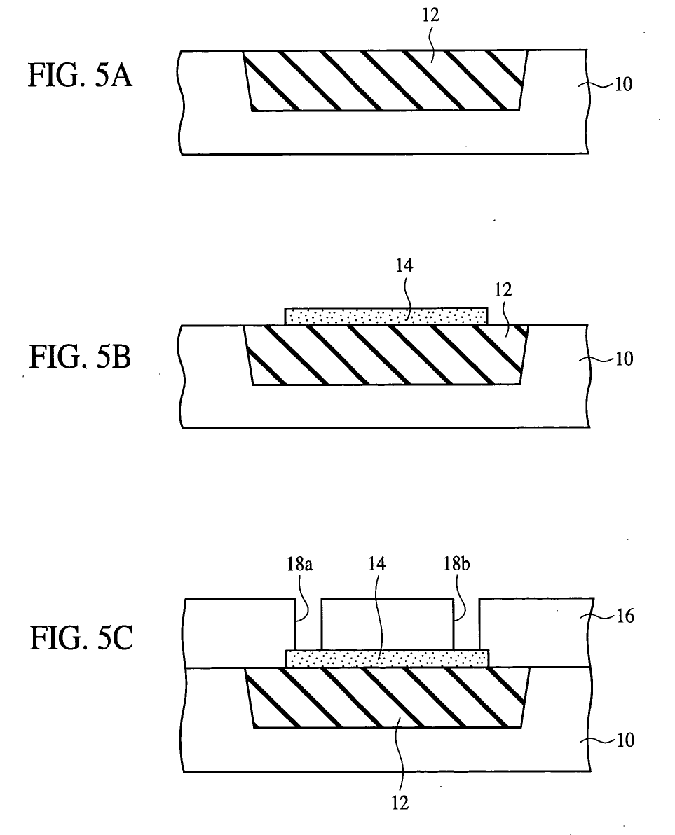

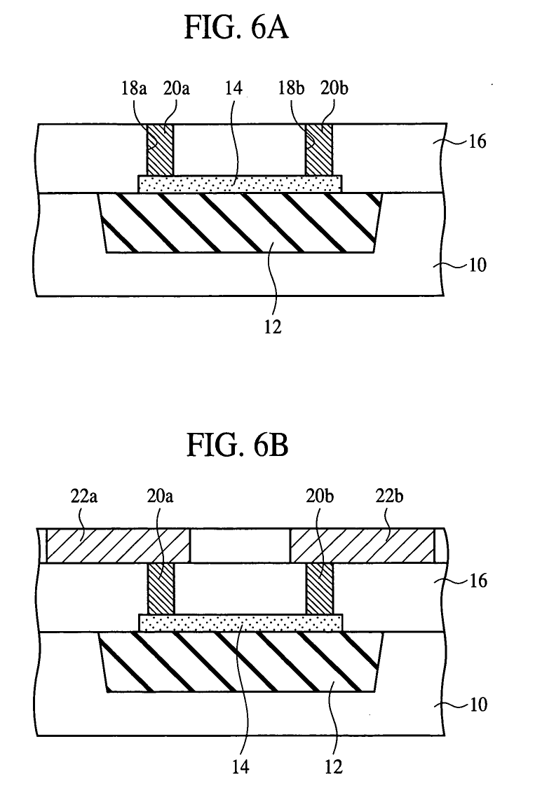

FIG. 1 is a plan view of the fuse according to the present embodiment. FIG. 2 is a diagrammatic sectional view of the fuse according to the present embodiment. FIG. 3 is a circuit diagram of one example of the fuse circuit. FIG. 4 is a diagrammatic sectional view showing the method for disconnecting the fuse according to the present embodiment. FIGS. 5A-5C and 6A-6B are sectional views of the fuse according to the present embodiment in the steps of the method for fabricating the same.

First, the structure of the fuse according to the present embodiment will be explained with reference to FIGS. 1 and 2.

A device isolation film 12 defining active regions is formed in the primary surface of a silicon substrate 10. An interconnection part 14 of polycrystalline silicon is formed on the device isolation film 12. An inter-layer insulating film 16 is formed on the silicon substrate 10 with the interconnection part 14 formed on. Contact plugs 20a, 20b are buried in the inter-layer insulating film 16, connected respectively to both ends of the interconnection part 14. The fuse of the contact plug 20b (a first contact part), the interconnection part 14 and the contact plug 20a (a second contact part) serially connected to each other is thus formed.

On the inter-layer insulating film 16 with the contact plugs 20a, 20b buried in, a metal interconnection 22a connected to one end of the interconnection part 14 via the contact plug 20a, and a metal interconnection 22b connected to the other end of the interconnection part 14 via the contact plug 20b are formed. The metal interconnection 22a is of the cathode electrode side, and the metal interconnection 22b is of the anode electrode side.

As described above, the fuse according to the present embodiment is characterized mainly in that the fuse has the interconnection part 14, the contact plug 20b (the first contact part) connected to one end of the interconnection part 14, and the contact plug 20a (the second contact part) connected to the other end of the interconnection part 14. The fuse according to the present embodiment changes the connection resistance between the interconnection part and the contact part and includes the interconnection part and the contact part to thereby function as a fuse. The fuse according to the present embodiment is different in this point from the conventional fuses, in which the resistance values of the polycrystalline silicon interconnection and the polycide interconnection themselves are changed.

The fuse shown in FIGS. 1 and 2 is incorporated in a fuse programming circuit as exemplified in FIG. 3 and is programmed as required. As shown in FIG. 3, sense transistors 32, 34 are connected respectively to both ends of the fuse 30. The connection terminal between the fuse 30 and the sense transistor 32 is grounded via a disconnection transistor 36. The connection terminal between the fuse 30 and the sense transistor 32 is connected to a fuse disconnection control circuit which applies a required voltage upon disconnecting the fuse.

Next, the method for disconnecting the fuse according to the present embodiment will be explained with reference to FIGS. 3 and 4. In the specification of the present application, “disconnecting” the fuse means programming the fuse and includes electrically completely separating the electrical connection and increasing the connection resistance.

In disconnecting the fuse, the sense transistors 32, 34 connected to both ends of the fuse 20 are tuned off. In this state a control voltage is applied to the gate terminal of the disconnection transistor 36 for, e.g., about 500 μsec to turn on the disconnection transistor 36.

At this time, a prescribed voltage is outputted from the fuse disconnection control circuit, whereby a current path is formed from the fuse disconnection control circuit to the ground potential via the fuse 30 and the disconnection transistor 36, and current flows in the fuse 30.

The current is flowed through the fuse 30 from the metal interconnection 22b to the metal interconnection 22a, whereby temperature rise takes place due to the resistance heating in the contact between the contact plug 20a and the interconnection part 14, whose sectional area is small. According to the result of the simulation made by the inventors of the present application, when a current of 4 mA is flowed in the contact of a 0.1 μm-diameter, the temperature of the contact was considered to instantaneously rise to about 1000° C.

In such high-temperature state, the tungsten (W) forming the contact plug 20a on the cathode electrode side migrates to the interconnection part 14 (see FIG. 4). The inventors of the present application made the TEM observation and the EDX analysis on the section and found that the disconnection transistor 36 is operated at 500 psec, whereby all the tungsten in the contact plug 20a on the cathode electrode side migrates to the interconnection part 14.

Such migration of the tungsten disconnects the contact plug 20a on the cathode electrode side and the interconnection part 14 with each other, and the electric connection between the metal interconnection 22a and the metal interconnection 22b is disconnected. Thus, the disconnection of the fuse is completed. The inventors of the present invention measured changes of the resistance value before and after the disconnection, and the resistance value after the disconnection was increased by about 6 places.

The voltage to be outputted from the fuse disconnection control circuit is suitably set in accordance with the size of the disconnection transistor 36, the length of the interconnection part 14, the contact area, etc. so that the current flowing in the contact between the contact plug 20a and the interconnection part 14 has a current density of not less than 5×10⁶ A·cm ⁻² and not more than 5×10⁸ A·cm⁻². The current density is set at not less than 5×10⁶ A·cm⁻², because the current density of less than 5×10⁶ A·cm⁻² cannot sufficiently migrate the metal material of the contact plug, and the current density is set at not more than 5×10⁸ A·cm⁻², because the current density of more than 5×10⁸ A·cm⁻² melts off the interconnection part 14, with a resultant risk that cracks may be formed in the inter-layer insulating film 16, etc.

For the fuse disconnection, pulse current of not more than 5 seconds is preferably used. The pulse current of more than 5 seconds increases the temperature of even the peripheral elements outside the fuse region, with a resultant risk that characteristics may be changed.

The interconnection part 14 may be formed of amorphous silicon, silicon germanium or others other than polycrystalline silicon.

The disconnection of the fuse by the above-described process can be completed in a very short period of time of about 500 μsec, and accordingly the temperature rise can be limited locally to the region of the interconnection part 14, whereby the influence on the peripheral elements can be prevented. The method for disconnecting the fuse according to the present embodiment does not use the melt and explosion the conventional methods resort to but uses the migration, and accordingly no cracks are formed in the inter-layer insulating film 16. Accordingly, means, such as a guard ring or others, for preventing the cracks is unnecessary, which allows the fuse circuit region to be downsized. There is no risk of disconnection, etc. of interconnections near the fuse, which improve the reliability of the fuse. The fuse is formed only of the interconnection part 14 of polycrystalline silicon and the contact plugs 20, whereby the fuse can be realized without addition excessive steps, which lowers the fabrication cost.

Next, the method for fabricating the fuse according to the present embodiment will be explained with reference to FIGS. 5A-6B.

First, the device isolation film 12 defining active regions is formed in the silicon substrate 10 by, e.g., STI (Shallow Trench Isolation) method (FIG. 5A).

Then, a polycrystalline silicon film of, e.g., a 150 nm-thickness is deposited on the entire surface by, e.g., CVD method. In place of polycrystalline silicon film, amorphous silicon may be deposited.

Next, the polycrystalline silicon film is patterned by photolithography and dry etching to form the interconnection part 14 of the polycrystalline silicon film on the device isolation film 12 (FIG. 5B). The size of the interconnection part is, e.g., a 0.20 μm-width and a 0.60 μm-length.

In the fuse according to the present embodiment, the interconnection part 14 is disposed on the device isolation film 12 for improving the heat efficiency in the disconnection. That is, the interconnection part 14 is disposed on the device isolation film 12, whereby the heat generated by flowing current to the interconnection part 14 is hindered from being conducted and escaping through the substrate, and accordingly the temperature of the interconnection part 14 can be easily raised to facilitate the disconnection of the fuse.

Next, a silicon oxide film of, e.g., a 700 nm-thickness is deposited on the silicon substrate 10 with the interconnection part 14 formed on. Then, the planarization is conducted by CMP (Chemical Mechanical Polishing) method to reduce the thickness of the silicon oxide film to 300 nm on the silicon substrate. Thus, the inter-layer insulating film 16 of the silicon oxide film is formed.

Preferably, the inter-layer insulating film 16 to be formed on the interconnection part 14 is formed of an insulating film of relatively high strength, such as SiO₂, SiON, SiN, PSG, BPSG or others. This is because if the inter-layer insulating film 16 is formed of a low dielectric constant film or a porous film of low strength, there is the risk that even the method for disconnecting the fuse according to the present embodiment might cause defects of causing damages, as of cracks, etc. and disconnection of the interconnection.

Then, contact holes 18a, 18b are formed in the inter-layer insulating film 16 respectively down to both ends of the interconnection part 14 by photolithography and dry etching (FIG. 5C). The diameter of the contact holes 18a, 18b is, e.g., 0.1 μm.

Next, a Ti film of, e.g., a 5 nm-thickness and a TiN film of, e.g., a 10 nm-thickness are deposited on the entire surface by, e.g., sputtering method or CVD method to form an adhesion layer of the Ti film and the TiN film.

Then, a tungsten film of, e.g., a 300 nm-thickness is deposited on the adhesion layer by, e.g., CVD method.

Next, the tungsten film and the adhesion layer are polished by, e.g., CMP method until the surface of the inter-layer insulating film 16 is exposed to thereby form the contact plug 20a of the adhesion layer and the tungsten film buried in the contact hole 18a, and the contact plug 20b of the adhesion layer and the tungsten film buried in the contact hole 18b (FIG. 6A).

Next, on the inter-layer insulating film 16 with the contact plugs 20a, 20b buried in, the metal interconnection 22a connected to one end of the interconnection part 14 via the contact plug 20a, and the metal interconnection 22b connected to the other end of the interconnection part 14 via the contact plug 20b are formed (FIG. 6B).

The metal interconnections 22a, 22b may be interconnections of, e.g., aluminum formed by depositing and patterning a conductive film or interconnection of, e.g., copper or others formed by the so-called damascene method. In forming the metal interconnections 22a, 22b by the damascene method, the contact plugs 20 and the metal interconnections 22 may be formed integral. In this case, the copper or another forming the metal interconnection migrates, and the disconnection of the fuse is conducted.

Then, upper interconnection layers, etc. to be connected to the metal interconnections 22a, 22b are formed as required, and the fuse is completed.

As described above, according to the present embodiment, the fuse comprises the interconnection part of polycrystalline silicon film, a first contact part (the contact plug 20b) connected to one end of the interconnection part, and a second contact part (the contact plug 20a) connected to the other end of the interconnection part and containing a metal material, and current is flowed from the first contact part to the second contact part to migrate the metal material of the second contact part to the polycrystalline silicon to disconnect the fuse, whereby the peripheral elements are kept from being damaged in the disconnection of the fuse. Thus, the cracking of the inter-layer insulating film can be prevented without making the fuse circuit large. The first contact part and the second contact part can be completely disconnected by migrating the metal material of the contacts, whereby the resistance change between before and after the disconnection can be large.

[A Second Embodiment]

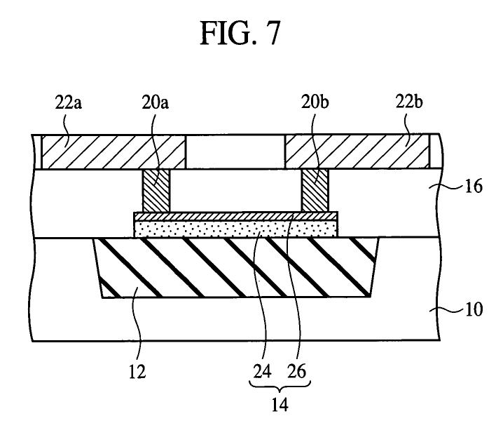

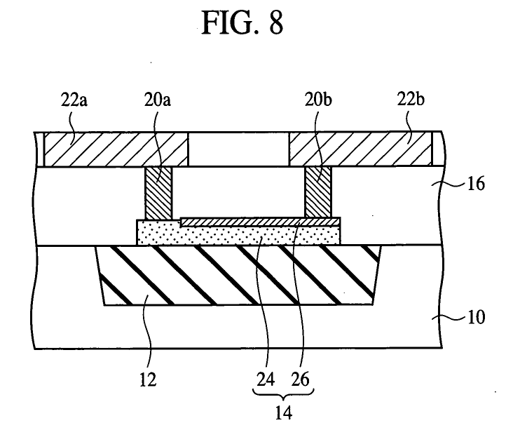

The fuse and the method for disconnecting the fuse according to a second embodiment of the present invention will be explained with reference to FIGS. 7 and 8. The same members of the fuse according to the first embodiment of the present invention shown in FIGS. 1 to 6 are represented by the same reference numbers not to repeat or to simplify their explanation.

FIG. 7 is a diagrammatic sectional view of the fuse according to the present embodiment. FIG. 8 is a diagrammatic sectional view showing another method for disconnecting the fuse according to the present embodiment.

First, the structure of the fuse according to the present embodiment will be explained with reference to FIG. 7.

A device isolation film 12 defining active regions is formed in the primary surface of a silicon substrate 10. An interconnection part 14 of the polycide structure of a polycrystalline silicon film 24 and a metal silicide film 26 laid the latter on the former is formed on the device isolation film 12. An inter-layer insulating film 16 is formed on the silicon substrate 10 with the interconnection part 14 formed on. In the inter-layer insulating film 16, contact plugs 20a, 20b are buried, connected respectively to both ends of the interconnection part 14. Thus, the fuse comprising the contact plug 20b, the interconnection part 14 and the contact plug 20a serially connected is constituted.

A metal interconnection 22a connected to one end of the interconnection part 14 via the contact plug 20a and a metal interconnection 22b connected to the other end of the interconnection part 14 via the contact plug 20b are formed on the inter-layer insulating film 16 with the contact plugs 20a, 20b buried in.

As described above, the fuse according to the present embodiment is the same as the fuse according to the first embodiment except that the interconnection part 14 has the polycide structure of the polycrystalline silicon film 24 and the metal silicide film 26. The method for disconnecting the fuse according to the first embodiment is applicable to the fuse according to the present embodiment, which includes the interconnection part 14 of the polycide structure.

In devices, such as a logic semiconductor device or others, whose high operation is important, gate electrodes of the polycide structure are often used for the gate resistance reduction. The interconnection part 14 of the fuse is usually formed concurrently with forming the gate electrodes. If the interconnection part 14 can be formed of the same polycide structure as the gate electrodes, the fuse can be formed without complicating the fabrication steps of the logic semiconductor device. Thus, the method for disconnecting the fuse according to the present invention, which can disconnect the interconnection part 14 of the polycide structure, is very effective.

In the interconnection part 14 of the polycide structure, the metal silicide film 26 formed on the polycrystalline silicon film 24 does not hinder the electromigration of the tungsten in the contact plug 20a to the polycrystalline silicon film 24. The metal element (e.g., Co) forming the metal silicide film 26 (e.g., cobalt silicide) also migrates to the anode electrode side. Thus, with the interconnection part 14 formed of the polycide structure, the connection between the contact plug 20a and the interconnection part 14 can be easily disconnected, and the resistance change between before and after the disconnection of the fuse can be large.

Preferably, no impurity is doped to the polycrystalline silicon film 24 forming the interconnection part 14, whereby the resistance value after the disconnection of the fuse can be large, and the circuit margin can be large.

In using the interconnection part 14 of the polycide structure, the migration of the metal material of the metal silicide film 26 (e.g., cobalt of cobalt silicide) alone can be caused by suitably setting the size of the disconnection transistor 36, the length of the interconnection part 14, the contact area, etc. That is, as shown in FIG. 8, the metal silicide film 26 on the cathode electrode side is transported to the anode electrode side to be away from the contact plug 20a, whereby the contact resistance between the contact plug 20a on the cathode electrode side and the interconnection part 14 is increased, and the disconnection of the fuse takes place.

In transporting the metal material of the metal silicide by the migration, the width of the polycrystalline silicon film 24 connected to the contact plug 20a on the cathode electrode side is preferably not more than 10 times the width of the contact plug 20.

The metal silicide film 26 on the polycrystalline silicon film 24 may be deposited on the polycrystalline silicon film 24 or may be formed by the usual salicide (self-aligned silicide) process or others.

As described above, according to the present embodiment, the fuse comprises the interconnection part of the polycide structure, a first contact part (the contact plug 20b) connected to one end of the interconnection part, a second contact part (the contact plug 20a) containing a metal material connected to the other end of the interconnection part, and current is flowed from the first contact part to the second contact part to migrate the metal material of the second contact part to the polycrystalline silicon to thereby disconnect the fuse, whereby the peripheral elements are hindered from being damaged in the disconnection of the fuse. Otherwise, the metal material forming the metal silicide film of the interconnection part migrated, to thereby disconnect the fuse, whereby the peripheral elements can be hindered from being damaged in the disconnection of the fuse. Thus, the inter-layer insulating film can be prevented from cracking without making the fuse circuit large. The first contact part and the second contact part can be completely disconnected by migrating the metal material of the contact parts, whereby the resistance change between before and after the disconnection of the fuse can be large.

[A Third Embodiment]

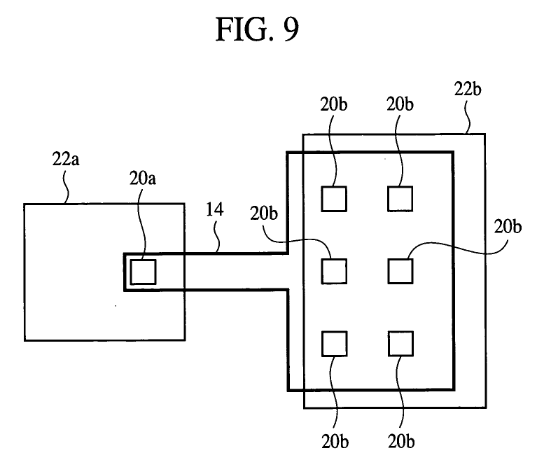

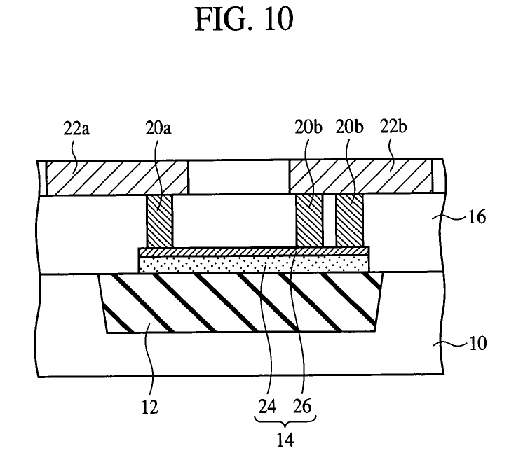

The fuse and the method for disconnecting the fuse according to a third embodiment of the present invention will be explained with reference to FIGS. 9 and 10. The same members of the present embodiment as those of the fuse according to the first and the second embodiments shown in FIGS. 1 to 8 are represented by the same reference numbers not to repeat or to simplify their explanation.

FIG. 9 is a plan view of the fuse according to the present embodiment. FIG. 10 is a diagrammatic sectional view of the fuse according to the present embodiment.

A device isolation film 12 defining active regions is formed in the primary surface of a silicon substrate 10. An interconnection part 14 of the polycide structure of a polycrystalline silicon film 24 and a metal silicide film 26 laid the latter on the former is formed on the device isolation film 12. The interconnection part 14 has a larger width on one end (the right side of the drawing) than on the other end (the left side of the drawing). An inter-layer insulating film 16 is formed on the silicon substrate 10 with the interconnection part 14 formed on. In the inter-layer insulating film 16, contact plugs 20a, 20b are buried, connected respectively to both ends of the interconnection part 14. A larger number of contact plugs 20b are formed on said one side of the interconnection part 14 than on said the other end of the interconnection part 14. Thus, the fuse includes the contact plugs 20b, the interconnection part 14 and the contact plug 20a serially connected.

A metal interconnection 22a connected to one end of the interconnection part 14 via the contact plug 20a and a metal interconnection 22b connected to the other end of the interconnection part 14 via the contact plug 20b are formed on the inter-layer insulating film 16 with the contact plugs 20a, 20b buried in.

As described above, the fuse according to the present embodiment is characterized in that the interconnection part 14 has a larger width on said one end associated with the anode electrode side of the interconnection part 14 (the right side of the drawing) than on said other end associated with the cathode electrode side of the interconnection part 14 (left side of the drawing), and the number of the contact plugs 20b connected to the interconnection part 14 is larger than the number of the contact plug 20a connected to the interconnection part 14.

The fuse is thus constituted, whereby the contact area between the interconnection part 14 and the metal interconnection 22b on the anode electrode side is larger, whereby the connection resistance can be smaller, and the temperature rise can be suppressed.

That is, the contact number on the anode electrode side is not less than twice the contact number on the cathode electrode side, whereby the resistance of the contact on the anode electrode side is not more than ½. The heat value is expressed by I²×R when a current value is indicated by I, and a resistance is indicated by R, and when the contact is twice, the heat value is ½. The metal migration on the anode electrode side can be prevented. The contact area between the interconnection part 14 and the contact plug 20b may be increased by the area of the contact plug 20b is increased in placing of increasing the number of the contact. The heat value on the anode electrode side can be ½ also by twice or more increasing the width of the interconnection part 14 on the anode electrode side.

Thus, the disadvantage of degrading the characteristics of the peripheral elements, etc. due to the migration of the tungsten forming the contact plugs 20b on the anode electrode side to the metal interconnection 22b.

As described above, according to the present embodiment, the interconnection part has the width increased on the anode electrode side than on the cathode electrode side, and the contact area connected to the interconnection part is lager on the anode electrode side than on the cathode electrode side, whereby the heat radiation efficiency of the interconnection part can be higher on the cathode electrode side. Thus, the metal material is prohibited from migrating from the contact plugs on the anode electrode side to the peripheral elements, etc. to thereby degrade the characteristics.

[A Fourth Embodiment]

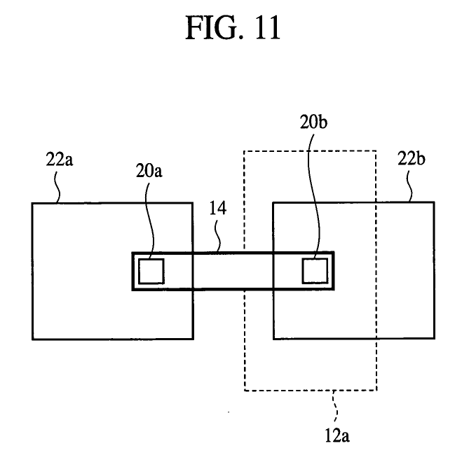

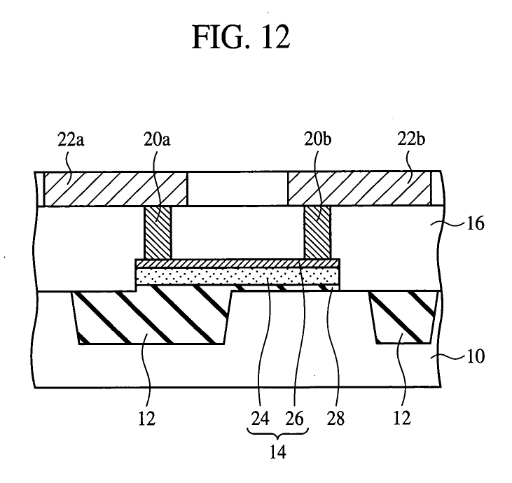

The fuse and the method for disconnecting the fuse according to a fourth embodiment of the present invention will be described with reference to FIGS. 11 and 12. The same members of the fuse according to the present embodiment as those of the fuse according to the first to the third embodiments shown in FIGS. 1 to 10 are represented by the same reference numbers not to repeat or to simplify their explanation.

FIG. 11 is a plan view of the fuse according to the present embodiment. FIG. 12 is a diagrammatic sectional view of the fuse according to the present embodiment.

A device isolation film 12 defining an active region 12a is formed in a primary surface of a silicon substrate 10. On the device isolation film 12, an interconnection part 14 of the polycide structure of a polycrystalline silicon film 24 and a metal silicide film 26 laid the latter on the former is formed with one end (on the right side of the drawing) positioned over the active region 12a of the silicon substrate 10 with an insulating film 28 interposed therebetween and with the other end (on the left side of the drawings) positioned on the device isolation film 12. An inter-layer insulating film 16 is formed on the silicon substrate 10 with the interconnection part 14 formed on. In the inter-layer insulating film 16, contact plugs 20a, 20b are buried, connected respectively to both ends of the interconnection part 14. Thus, the fuse comprising the contact plugs 20b, the interconnection part 14 and the contact plug 20a is constituted.

Metal interconnection 22a connected to said the other end of the interconnection part 14 via the contact plug 20a and a metal interconnection 22b connected to said one end of the interconnection part 14 via the contact plug 20b are formed on the inter-layer insulating film 16 with the contact plugs 20a, 20b buried in.

As described above, the fuse according to the present embodiment is characterized in that one end of the interconnection part 14, which is associated with the anode electrode side is extended over the active region 12a.

The interconnection part 14 extended over the active region 12a is formed on the silicon substrate 10 with a thin insulating film 28 interposed therebetween, which is formed concurrently with the gate insulating film of transistors. Accordingly, the formation of the interconnection part 14 over the active region 12a more facilitates the heat generated in the interconnection part 14 escaping toward the silicon substrate 10 than the formation of the interconnection part 14 on the device isolation. film 12.

The fuse is thus constituted, whereby on the anode electrode side, .the heat radiation efficiency of the interconnection part 14 is increased, and the temperature rise can be suppressed. Accordingly, the tungsten forming the contact plug 20b on the anode electrode side is hindered from migrating toward the metal interconnection 22b to flow into the peripheral devices, etc. to thereby cause disadvantages of the characteristic degradation, etc.

The area of the active region, .over which the interconnection part 14 is extended is preferably so large that the heat generated in the interconnection part 14 upon disconnecting the fuse can spread. As an example, the width of the interconnection part 14 is 0.3 μm, and the width of the active region 12a is 0.50 μm. It is preferable that the active region 12a is positioned nearer the anode electrode side with respect to the middle of the interconnection part 14.

As described above, according to the present embodiment, the interconnection part on the anode electrode side is formed over the active region, whereby the heat radiation efficiency on the anode electrode side can be increased. Thus, the metal material is prohibited from migrating from the contact plugs on the anode electrode side to the peripheral elements, etc. to thereby degrade the characteristics.

[A Fifth Embodiment]

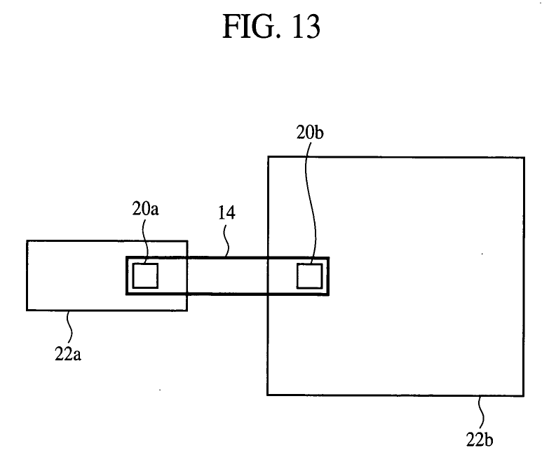

The fuse and the method for disconnecting the fuse according to a fifth embodiment of the present invention will be explained with reference to FIG. 13. The same members of the present embodiment as those of the fuse according to the first to the fourth embodiments shown in FIGS. 1 to 12 are represented by the same reference numbers not to repeat or to simplify their explanation.

FIG. 13 is a plan view of the fuse according to the present embodiment.

The fuse according to the present embodiment is the same as the fuse according to the second embodiment shown in FIGS. 7 and 8 except that they are different in the plane shape of the metal interconnection 22. That is, the fuse according to the present embodiment is characterized in that a metal interconnection 22b connected to the anode electrode side of an interconnection part 14 is larger than the width of a metal interconnection 22a connected to the cathode electrode side.

The fuse is thus constituted, whereby on the anode electrode side, the heat radiation efficiency on the interconnection part 14, and the temperature rise can be suppressed. Thus, disadvantages that the tungsten forming a contact plug 20b on the anode electrode side is hindered from migrating toward the metal interconnection 22b to flow into the peripheral elements, etc. to thereby cause the characteristic degradation, etc. can be prevented.

Preferably, the width of the metal interconnection 22a on the cathode electrode side is about twice the contact width so that the metal interconnection 22a is not melted off by the current upon disconnecting the fuse. However, when the metal interconnection 22a is too wide, the heat generated in the contact escape through the metal interconnection 22a, and the width of the metal interconnection 22a is preferably not more than 5 times. On the other hand, the width of the metal interconnection 22b on the anode electrode side is not less than twice the width of the metal interconnection 22a so as to prevent the metal migration on the anode electrode side.

As described above, according to the present embodiment, the width of the metal interconnection on the anode electrode side is larger than the width of the metal interconnection on the cathode electrode side, whereby the heat radiation efficiency of the interconnection part on the anode electrode side can be increased. Thus, the metal material is hindered from flowing the contact plug on the anode electrode side into the peripheral elements, etc. to thereby cause the characteristic degradation.

The thickness of the metal interconnection 22b on the anode electrode side of the fuse may be thicken than the thickness of the metal interconnection 22 a on the cathode electrode side of the fuse, whereby the heat radiation efficiency of the interconnection part on the anode electrode side can be increased.

[A Sixth Embodiment]

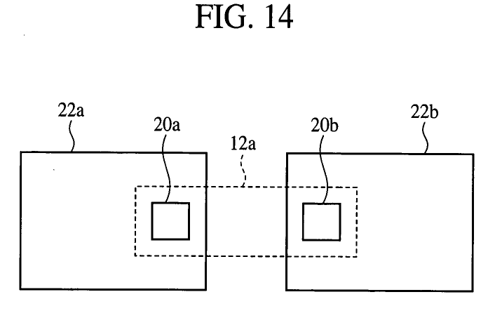

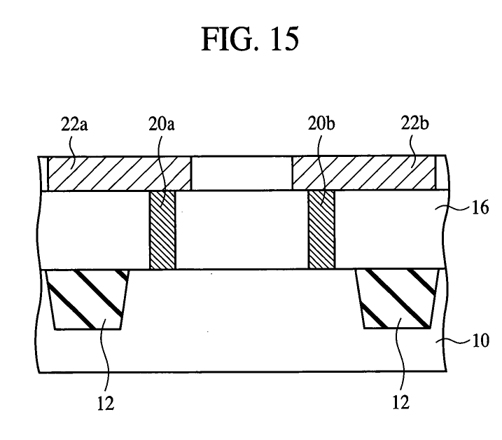

The fuse and the method for disconnecting the fuse according to a sixth embodiment of the present invention will be explained with reference to FIGS. 14 and 15. The same members of the present embodiment as those of the fuse according to the fist to the fifth embodiment shown in FIGS. 1 to 13 are represented by the same reference numbers not to repeat or to simplify their explanation.

FIG. 14 is a plan view of the fuse according to the present embodiment. FIG. 15 is a diagrammatic sectional view of the fuse according to the present embodiment.

A device isolation film 12 defining an active region 12a is formed in the primary surface of a silicon substrate 10. The active region 12a forms a part of the fuse. As shown in FIG. 14, the active region 12a has a rectangular plane shape which is elongated in one direction. In the specification of the present application, the active region 12a forming a part of the fuse is often called “an interconnection part”.

An inter-layer insulating film 16 is formed on the silicon substrate 10 with the device isolation film 12 formed on. In the inter-layer insulating film 16, contact plugs 20a, 20b are buried, connected respectively to both ends of the active region 12a. Thus, the fuse comprising the contact plugs 20b (a first contact part), the active region 12a (an interconnection part) and the contact plug 20a (a second contact part) serially connected is constituted.

On the inter-layer insulating film 16 with the contact plugs 20a, 20b buried in, a metal interconnection 22a connected to one end of the active region 12a via the contact plug 20a and a metal interconnection 22b connected to the other end of the active region 12a via the contact plug 20b are formed.

As described above, the fuse according to the present embodiment is characterized mainly in that the fuse comprises the interconnection part formed of the active region 12a, the contact plug 20a (a first contact part) connected to one end of the interconnection part and the contact plug 20a (a second contact part) connected to the other end of the interconnection part.

In the fuse having the current path via the silicon substrate 10 as well, current is flowed at a current density of not less than a prescribed value, whereby the tungsten is migrated from the contact plug 20a to the silicon substrate 10. Due to this migration of the tungsten, the contact plug 20a on the cathode electrode side is disconnected, and the electric connection between the metal interconnection 22a and the metal interconnection 22b can be disconnected.

As described above, according to the present embodiment, the fuse comprises the interconnection part formed of the silicon layer of the active region, the first contact part (the contact plug 20b) connected to one end of the interconnection part and the second contact part (the contact plug 20a) connected to the other end of the interconnection part and containing a metal material, and current is flowed from the side of the first contact part to the side of the second contact part to migrate the metal material of the second contact part to the silicon layer to thereby disconnect the fuse, whereby the peripheral elements, etc. can be kept from being damaged upon disconnecting the fuse. Thus, without making the fuse circuit large, the inter-layer insulating film is kept from cracking. The metal of the contact is migrated to thereby completely undo the connection between the first contact part and the second contact part, whereby the resistance change between before and after the disconnection of the fuse can be large.

[A Seventh Embodiment]

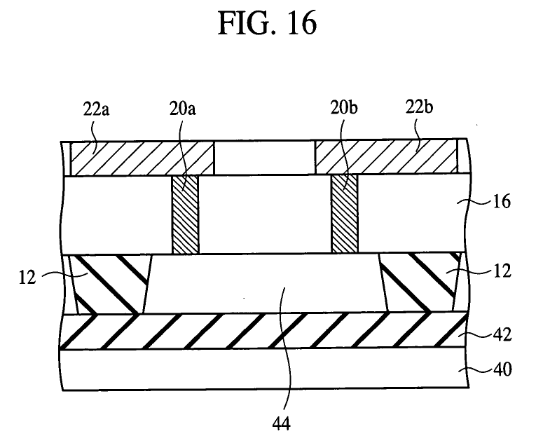

The fuse and the method for disconnecting the fuse according to a seventh embodiment of the present invention will be explained with reference to FIG. 16. The same members of the present embodiment as those of the fuse according to the first to the sixth embodiments shown in FIGS. 1 to 15 are represented by the same reference numbers not to repeat or to simplify their explanation.

FIG. 16 is a diagrammatic sectional view of the fuse according to the present embodiment.

The fuse according to the present embodiment is the same as the fuse according to the sixth embodiment except that an SOI substrate 40 is used as the substrate.

The SOI substrate 40 includes a buried insulating layer 42 and an SOI layer 44 formed on the buried insulating layer 42, which are formed on the surface. A device isolation film is formed in the SOI layer with the underside connected to the buried insulating layer 42. The same fuse as the fuse according to the sixth embodiment is formed on the active region 12a defined by the device isolation film 12.

The fuse is formed on the SOI substrate 40, whereby the active region 12a which is the current path of the fuse is completely surrounded by the device isolation film 12 and the buried insulating layer 42. Accordingly, even if the metal should migrate from the contact plug 20a to the active region 12a upon disconnecting the fuse, the metal can be confined in the fuse region. Thus, the metal is hindered from arriving even at the peripheral elements, etc. to thereby cause the characteristic degradation.

The structure of the fuse according to the present embodiment is very effective in using a material especially having a large diffusion coefficient in silicon (e.g., copper) as the contact metal.

As described above, according to the present embodiment, the fuse is fabricated on the SOI substrate,. whereby even with the first contact part formed in the silicon layer of the active region, the metal material flowing into the silicon layer is prevented from arriving at the peripheral elements to thereby cause the characteristic degradation.

[Modified Embodiments]

The present invention is not limited to the above-described embodiments and can cover other various modifications.

For example, in the second to the fifth embodiments, the interconnection part 14 is formed of the polycide structure of polycrystalline silicon film and metal silicide film, but the interconnection part 14 may be formed of a single polycrystalline silicon layer.

In the third embodiment, the number of the contact plug 20b connected to the interconnection part 14 on the anode electrode side of the fuse according to the second embodiment is larger than that of the contact plug 20a connected to the interconnection part 14 on the cathode electrode side. In the fuse according to the fourth to the seventh embodiments, the number of the contact plug 20b connected to the interconnection part 14 or the active region 12a on the anode electrode side may be larger than the number of the contact plug 20a connected to the interconnection part 14 or the active region 12a on the cathode electrode side. Thus, the heat radiation efficiency on the anode electrode side can be further increased.

In the fourth embodiment, a part of the interconnection part 14 of the fuse according to the second embodiment is formed over the active region 12a. In the fuse according to the fifth embodiment, also, a part of the interconnection part on the anode electrode side may be formed over the active region 12a. Thus, the heat radiation efficiency to the anode electrode side can be further increased.

In the fifth embodiment, the width of the metal interconnection 22b on the anode electrode side of the fuse according to the second embodiment is larger than the width of the metal interconnection 22a on the cathode electrode side. In the fuse according to the sixth and the seventh embodiments, also, the width of the metal interconnection 22b on the anode electrode side may be larger than the width of the metal interconnection 22a on the cathode electrode side. Thus, the heat radiation on the anode electrode side can be further increased.

In the first to the seventh embodiments, the contact plugs 20a, 20b are tungsten plugs buried in the inter-layer insulating film 16. However, the contact pugs 20a, 20b may be contact plugs of an interconnection material other than copper or others. The contact plugs 20a, 20b may be via-portions of the interconnection layer formed integral with the metal interconnections 22a, 22b. The contact plugs may be formed of a metal material, e.g., a conductive material containing, e.g., tungsten, copper, aluminum or others, which is migrated by flowing current.

In the sixth ad the seventh embodiments, a part of the interconnection part of the fuse is formed of the active region 12a. However, a metal silicide film may be formed on the active region 12a, whereby, as in the second embodiment, the metal material forming the metal silicide film can be migrated to thereby change the resistance value of the fuse.

The contact plugs may include a barrier metal of titanium (Ti), titanium nitride (TiN), tungsten, tungsten nitride (WN), tantalum (Ta), tantalum nitride (TaN) or others.

What is claimed is:

1. A fuse comprising:
an interconnection part including a silicon layer;
a first contact part connected to one end of the interconnection part and containing a metal material; and
a second contact part connected to the other end of the interconnection part and containing a metal material.

2. A fuse comprising: an interconnection part including a silicon layer; a first contact part connected to one end of the interconnection part and containing a metal material; and a second contact part connected to the other end of the interconnection part and containing a metal material,
after disconnecting, at least a part of the metal material forming the second contact part being migrated to the interconnection part, and-the interconnection part and the second contact part being electrically disconnected.

3. A fuse comprising: an interconnection part including a silicon layer and a metal silicide layer formed on the silicon layer; a first contact part connected to one end of the interconnection part; and a second contact part connected to the other end of the interconnection part,
after disconnecting, at least a part of a metal material forming the metal silicide layer being migrated to the interconnection part, and the interconnection part and the second contact part being electrically disconnected.

4. A semiconductor device comprising:
a fuse including:
an interconnection part including a silicon layer;
a first contact part connected to one end of the interconnection part and containing a metal material; and
a second contact part connected to the other end of the interconnection part and containing a metal material.

5. A semiconductor device according to claim 4, wherein
the interconnection part further comprises a metal silicide layer formed on the silicon layer.

6. A semiconductor device according to claim 4, wherein
a width of the interconnection part in a region contacting the first contact part is larger than a width of the interconnection part in a region contacting the second contact part.

7. A semiconductor device according to claim 4, wherein
an area of a contact between the interconnection part and the first contact part is larger than an area of a contact between the interconnection part and the second contact part.

8. A semiconductor device according to claim 4, wherein
a contact region between the interconnection part and the first contact part, and a contact region between the interconnection part and the second contact part are formed over a device isolation film.

9. A semiconductor device according to claim 4, wherein
a contact region between the interconnection part and the first contact part is formed over an active region, and
a contact region between the interconnection part and the second contact is formed over a device isolation film.

10. A semiconductor device according to claim 4, wherein
a width of a first interconnection connected to the first contact part is larger than a width of a second interconnection connected to the second contact part.

11. A semiconductor device according to claim 4, wherein
a first interconnection connected to the first contact part is thicker than a second interconnection connected to the second contact part.

12. A semiconductor device according to claim 10, wherein
the first interconnection and the first contact part, and the second interconnection and the second contact part are respectively formed integral.

13. A semiconductor device according to claim 11, wherein
the first interconnection and the first contact part, and the second interconnection and the second contact part are respectively formed integral.

14. A method for disconnecting a fuse comprising an interconnection part including a silicon layer; a first contact part connected to one end of the interconnection part; and a second contact connected to the other end of the interconnection part and containing a metal material,
a current being flowed from the first contact part to the second contact part via the interconnection part to migrate the metal material of the second contact part to the silicon layer to thereby change a connection resistance between the interconnection part and the second contact part.

15. A method for disconnecting a fuse comprising an interconnection part including a silicon layer and a metal silicide layer formed on the silicon layer; a first contact part connected to one end of the interconnection part; and a second contact part connected to the other end of the interconnection part,
a current being flowed from the first contact part to the second contact part via the interconnection part to migrate a metal material forming the metal silicide layer to a side of the first contact part to thereby change a contact resistance between the interconnection part and the second contact part.

16. A method for disconnecting a fuse according to claim 14, wherein
a current value of the current flowed from the first contact part to the second contact part is so set that a current density in the contact part is not less than 5×10⁶ A·cm⁻² and not more than 5×10⁸ A·cm⁻².

17. A method for disconnecting a fuse according to claim 15, wherein
a current value of the current flowed from the first contact part to the second contact part is so set that a current density in the contact part is not less than 5×10⁶ A·cm⁻² and not more than 5×10⁸ A·cm⁻².

18. A method for disconnecting a fuse according to claim 14, wherein
the current flowed from the first contact part to the second contact part is a pulse current of not more than 5 seconds.

19. A method for disconnecting a fuse according to claim 15, wherein
the current flowed from the first contact part to the second contact part is a pulse current of not more than 5 seconds.
